(19) United States
(12) Patent Application Publication
(10) Pub. No.: US 2004/0025931 A1
(43) Pub. Date: Feb. 12, 2004

(54) Solar panel for simultaneous generation of electric and thermal energy

(75) Inventor: Jorge Miguel Aguglia, Lecce (IT)

Correspondence Address: GREER, BURNS & CRAIN, LTD., 300 S. Wacker Drive - 25th Floor, Chicago, IL, 60606, US

(73) Assignee: S.I.E.M. S.R.L.

(21) Appl. No.: 10/216,328

(22) Filed: Aug. 9, 2002

(51) Int. Cl. H01L 31/00

(52) U.S. Cl. 136/246

(57) ABSTRACT

A solar panel for simultaneous generation of electric and thermal energy with efficiency improvements is disclosed. A combined panel provided with a photovoltaic panel thermally contacting a fluid-containing panel by means of a heat exchanger, has reflective means mounted thereon for directing solar radiation to the photosensitive surface of the photovoltaic panel. The increased light concentration together with the cooling action of the water circulating in the fluid-containing panel, permits to highly increase the electric energy generated by the photovoltaic panel and the thermal power carried outside the fluid-containing panel by means of the water.

### BACKGROUND OF THE INVENTION

The present invention relates to a solar panel for simultaneous generation of electric and thermal energy, particularly suitable for autonomous power generation systems.

Solar energy is the greatest source of energy that can currently be tapped from our planet; this form of energy is used mostly at the domestic and industrial level to produce electric power and heat.

Solar radiation deposits on Earth's surface an energy that depends on the climate, the latitude and the altitude; in optimum conditions and at maximum intensity, the average solar energy available at ground level is approximately 1.5 kW/m². However, regions with high direct insolation cover a limited fraction of Earth's surface, and common environmental conditions always entail the presence of atmospheric phenomena, such as cloud layers, that cause solar radiation to be no longer direct but diffused: in other words, the concentration of light energy per unit surface is reduced by phenomena that are linked for example to atmospheric humidity, which randomly deflect the path of sunrays by multiple successive reflections and refractions and attenuate the energy they carry by absorption.

The photovoltaic panel is the currently known device that allows to convert solar energy into electric power even in the presence of light absorption and diffusion; clearly, the generated electric power varies according to the illumination and therefore not only according to the atmospheric conditions but also according to the season and the time of the day.

So-called “combined” solar panels are also known which are characterized in that they have a hydraulic circuit arranged below the photovoltaic panel and in thermal contact therewith; they are used to recover part of the heat absorbed by the panel, making it available for various uses, such as for example the heating of indoor spaces.

In order to receive sufficient illumination, solar panels must be orientated appropriately toward the sun; current systems generally choose a fixed orientation in which the panels are directed southward, with an inclination with respect to the horizon (azimuth) that is equal to the latitude of the location where they are installed.

Conversion from solar energy to electric power occurs with a certain efficiency, defined as the ratio between received energy and output energy, that in current systems is much lower than one (typically it is on the order of 10%). Conversion efficiency, as regards photovoltaic panels, is mainly limited by two factors: the structure of the panel and the type of materials used for the photovoltaic cells. Typically, the cells are made of monocrystalline or polycrystalline semiconductor material; depending on the material used, one has conversion efficiencies of 14-16% for monocrystalline materials and 11-13% for polycrystalline materials.

Photothermal conversion efficiencies, i.e., the conversion efficiencies from solar energy to thermal energy, are instead much higher and are typically approximately 70-80%.

A glass plate is used to protect photovoltaic cells from bad weather; if it has an appropriate thickness and chemical treatment, said plate can also act as a nonreflective layer, i.e., as a layer that can minimize and even eliminate the percentage of light reflected at the air-glass interface, thus maximizing the amount of light transmitted toward the photovoltaic cells.

Known combined panels are inherently incomplete in their use of the thermal part of their structure, since the goal of producing thermal energy simultaneously with electric power prevails, in a sense, on the great advantage of cooling the photovoltaic panel; the generated thermal power is an end unto itself and the potential of a cooling system is not exploited adequately.

### SUMMARY OF THE INVENTION

The aim of the present invention is to improve the performance of photovoltaic panels by devising a method for solar energy conversion and a type of panel that in addition to combining the technology of photovoltaic panels with the technology of thermal panels at the same time improves the collection of solar energy, increasing its utilization to produce electric and thermal energy.

Within this aim, an object of the invention is to use a cooling system that is capable of lowering the temperature of photovoltaic cells, consequently increasing photoelectric conversion efficiency.

Another object of the invention is to regulate the cooling system according to the degree of illumination to which the panel is subjected.

Another object is to use the cooling system to produce thermal energy, which can then be used or stored or converted thermoelectrically.

This aim and these and other objects that will become better apparent hereinafter are achieved by the solar panel for simultaneous generation of electric and thermal energy according to the invention, characterized in that it comprises a photovoltaic panel for generating electric energy, a supporting frame on which said photovoltaic panel is mounted, a fluid-containing panel for cooling the photovoltaic panel and for generating thermal energy that is mounted on the surface that lies opposite the surface of the photovoltaic panel that is substantially directed toward the sun, a heat exchanger that is interposed between said photovoltaic panel and said fluid-containing panel to provide the thermal coupling between said photovoltaic panel and said fluid-containing panel, and reflective means fitted on said supporting frame and orientated so as to concentrate solar radiation on said photovoltaic panel.

### BRIEF DESCRIPTION OF THE DRAWINGS

Further characteristics and advantages of the invention will become better apparent from the description of preferred but not exclusive embodiments of the proposed solar panel, illustrated only by way of non-limitative example in the accompanying drawings, wherein:

FIG. 1 is a schematic view of the layered structure of a generic combined solar panel;

FIG. 2 is a fragmentary sectional view of the peripheral region of the combined solar panel;

FIG. 3 is a view of an embodiment of the fluid-containing panel that uses a hydraulic circuit of the coil type;

FIG. 4 is a view of a detail of one of the partitions of the circuit of FIG. 3;

FIG. 5 is a fragmentary sectional view of the solar panel according to the invention;

FIG. 6 is a sectional view of the complete panel, which is sized in particular according to an ideal direction of the rays that is perpendicular to the plane of exposure of the panel;

FIG. 7 is a plan view of the panel according to the invention;

FIG. 8 is a perspective view of the panel according to the invention;

FIG. 9 is a schematic view of a possible apparatus for using and/or storing energy, which can be connected electrically or hydraulically to the panel according to the invention;

FIG. 10 is a schematic view of a particular arrangement of a succession of three solar modules according to the invention.

### DESCRIPTION OF THE PREFERRED EMBODIMENTS

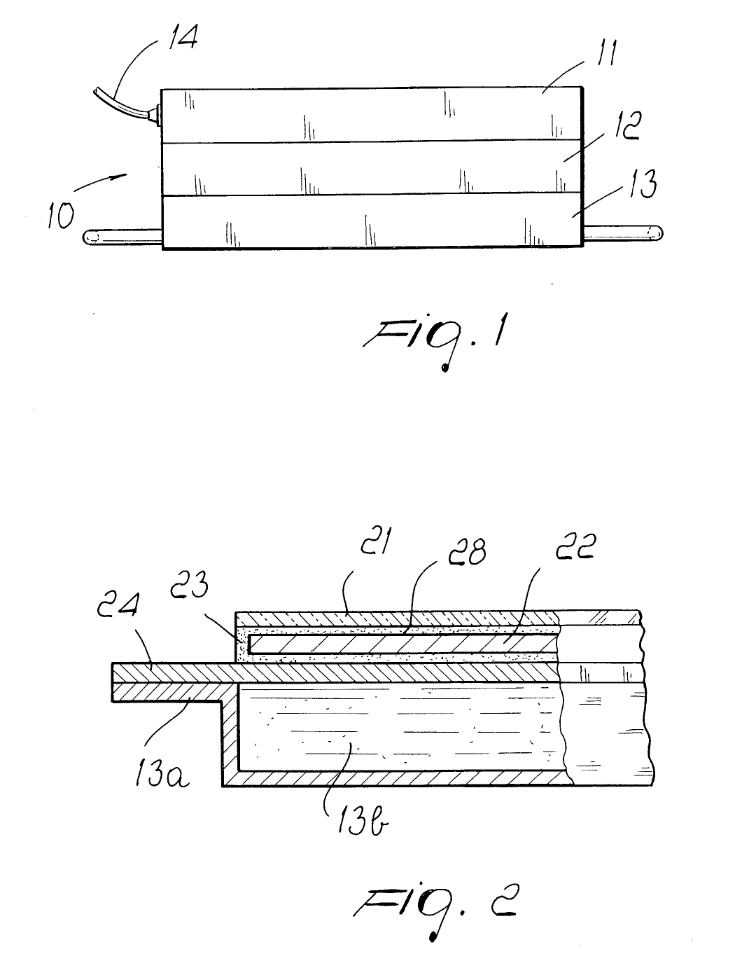

With reference to FIGS. 1 to 4, a combined solar panel 10 is composed mainly of at least three components that can be mutually distinguished and are mutually thermally connected: a photovoltaic panel 11, a heat exchanger 12, and a fluid-containing panel 13.

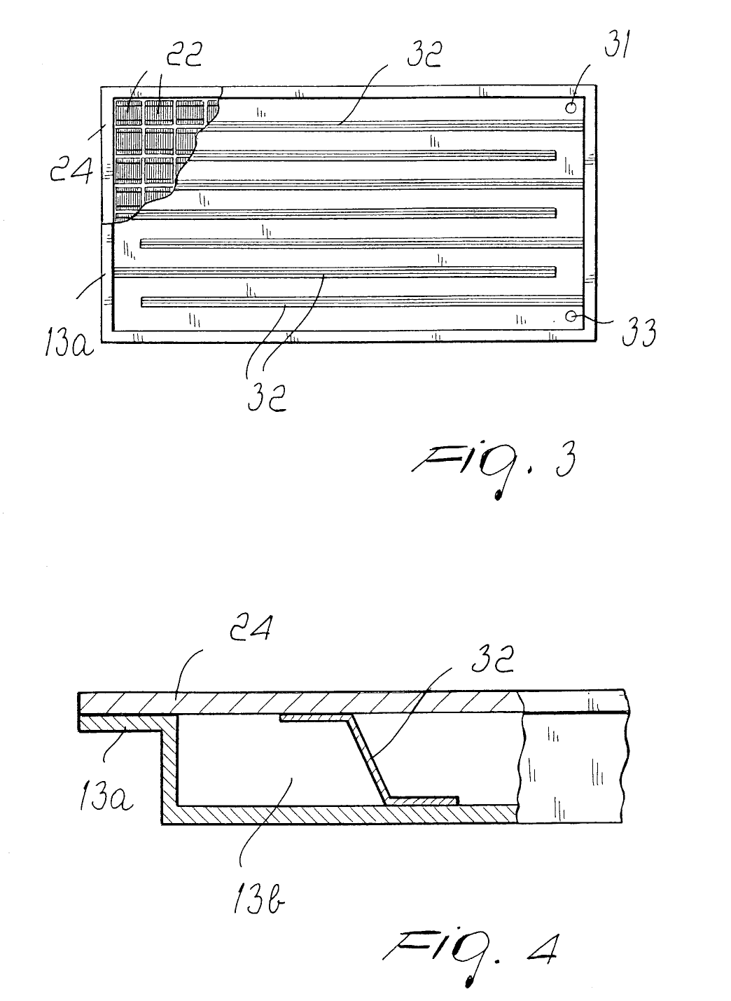

The photovoltaic panel 11 comprises an electrical output 14 and a series of superimposed layers, particularly a transparent protective layer 21, typically made of glass, that is fixed to a structure that is composed of at least one photovoltaic cell 22 by virtue of an adhesive 23 such as for example ethyl vinyl acetate (EVA); FIG. 2 illustrates a single photovoltaic cell, but typically multiple cells are used and are arranged on a same plane so as to form an array or module, whose dimensions vary according to the applications. The photovoltaic cell 22 is in turn fixed to the heat exchanger 12 by virtue of the same adhesive 23.

Hereinafter, reference is made equally to a cell or an array of cells without specifying their dimensions or number except in the specific examples.

In a particular embodiment of the invention, the heat exchanger 12 is constituted (FIG. 2) by a heat-conducting plate 24, which is interposed between the photovoltaic panel and the fluid-containing panel and has a surface area that is equal to, or greater than, the area of the array of photovoltaic cells. In particular, the heat-conducting plate is fixed, by means of the adhesive 23, to the surface of the photovoltaic panel that lies opposite the surface 28 that is directed substantially toward the sun, and has the same thermal expansion coefficient as the transparent protective layer 21, i.e., as glass; this feature arises from the fact that the panel according to the present invention is subjected to high temperatures, which cause expansion of the materials that compose it. If the expansion coefficients were different, the layers might slip with respect to each other, leading to separation of some parts, with a considerable drop in the efficiency of the panel.

Preferably, the heat-conducting plate 24 is made of steel, for example AISI442, which has the same expansion coefficient as glass, and is also fixed to the fluid-containing panel.

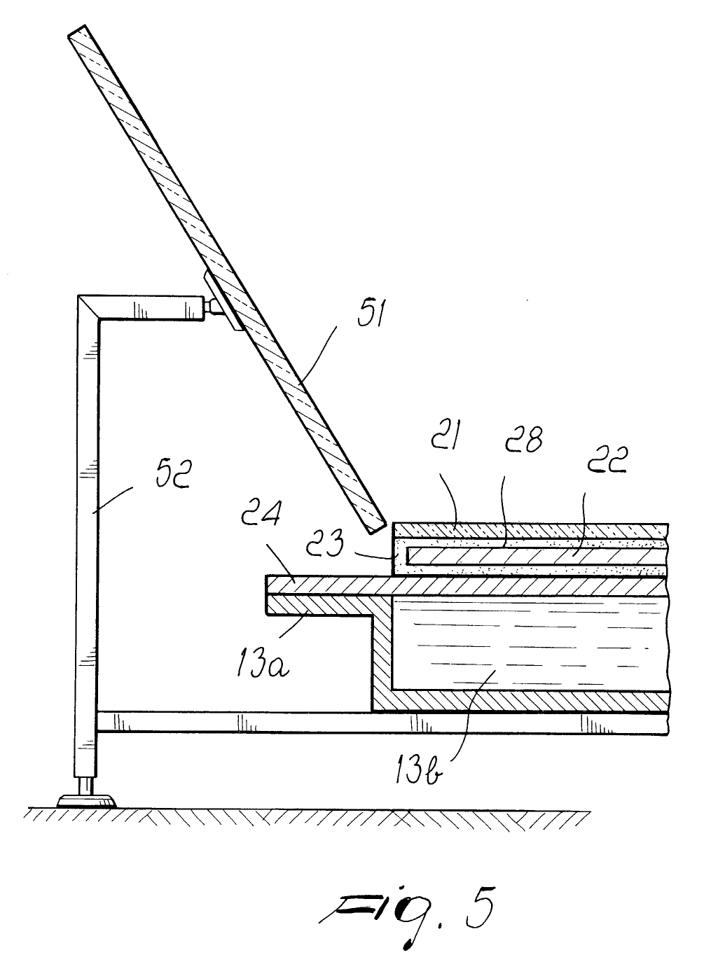

The fluid-containing panel 13 comprises (FIGS. 2 and 5) a compartment 13a, preferably made of the same material as the heat-conducting plate 24, which contains a hydraulic circuit 13b; the internal structure of the hydraulic circuit can have the particular configuration shown in FIGS. 3 and 4. In this configuration there is a series of partitions 32, arranged parallel to each other so as to convey the fluid along a winding line path from an input mouth 31 to an output mouth 33; these mouths represent the connection to the outside of the hydraulic circuit of the fluid-containing panel.

The individual partition 32 of the particular embodiment of the fluid-containing panel (FIG. 4) preferably has a profile that connects the heat-conducting plate 24 to the bottom of the compartment 13a, shown in FIG. 4.

A panel built in this manner can be applied immediately in home systems.

In a second embodiment of the fluid-containing panel, not shown in the figures, the fluid-containing panel is constituted by a compartment that consists of a tank filled with water, on which the photovoltaic panel and the heat exchanger float by means of a raft that is connected to the bottom by means of ties: in this case, the hydraulic circuit is formed solely by the interior of the tank and by the connectors for filling and changing the water in the tank.

This second type of structure is suitable for applications such as fish farming, in which the obvious benefits of heating the water are combined with the usefulness of producing electric power for example to supply a pump for moving the water, in order to increase its oxygenation and reduce algae formation.

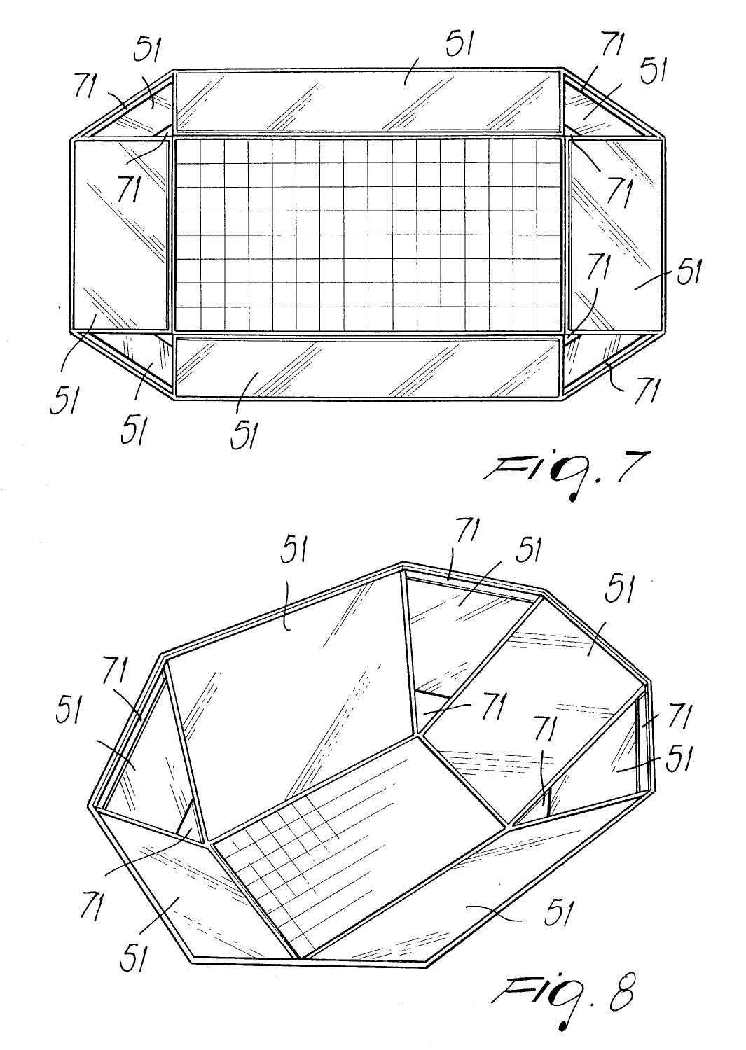

With reference to FIGS. 5 to 8, the combined panel is fixed to a supporting frame 52, on which light-reflecting or -concentrating means 51 are mounted; said means are preferably constituted by flat mirrors or by dielectric multilayers (for example Bragg reflectors with inclined planes) or by other possible light bending or redirecting elements. These reflective means 51 are preferably mounted along the perimeter or in any case at least along one side of the combined panel, are rigidly coupled thereto, and are orientated so as to reflect the light that is incident on them toward the photovoltaic panel. With particular reference to FIGS. 7 and 8, the panel has mirrors mounted along the entire perimeter of the photovoltaic panel, including the corners; preferably, the overall structure has openings 71 that allow the passage of wind and thus help to increase the solidity of the structure with respect to wind-type phenomena.

The panel is preferably sized by assuming a normal incidence of the solar rays with respect to the plane of the photovoltaic panel; this of course does not prevent one from sizing all the components of the panel by choosing as reference a different type of incidence.

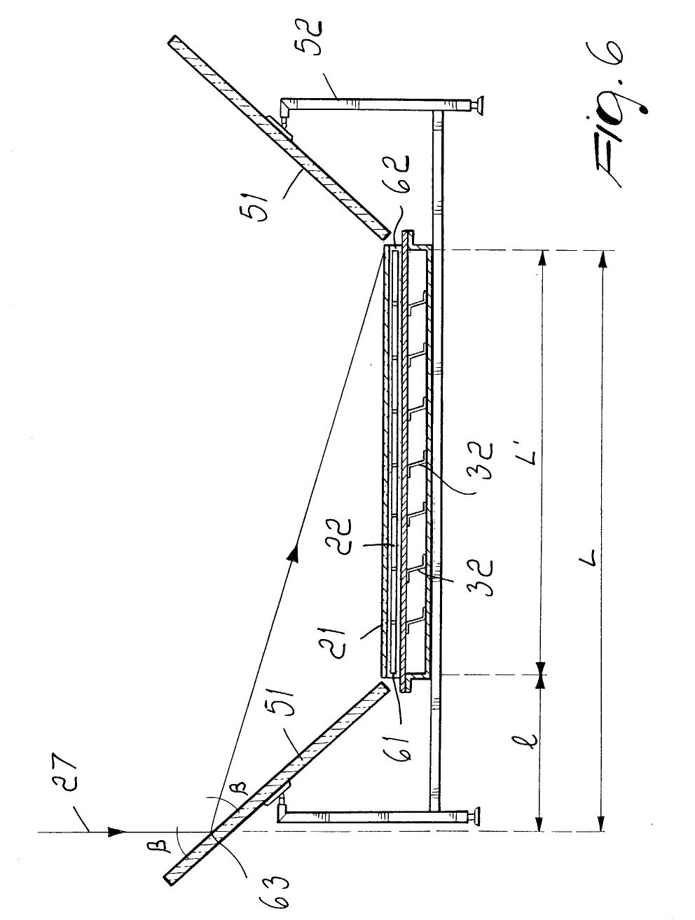

FIG. 6 illustrates the particular case in which the rays 27, which are normal to the plane of the surface 28 that is substantially directed toward the sun of the photovoltaic cell 22, are incident to the mirrors at an angle beta (β) with respect to the plane of the mirror being considered. Obviously, the acute angle formed between the mirror being considered and the plane of the panel is the complementary of beta and is generally designated hereinafter as mirror inclination.

The photovoltaic panel 11 is capable of converting part of the energy contained in solar radiation into electrical potential energy by virtue of the exchange of energy that occurs between photons at a given wavelength range and electrons of the material that constitutes the core of the panel, i.e., the photovoltaic cell 22.

As mentioned, the conversion from photon energy to electrical potential energy has a certain efficiency owing both to physical reasons (efficiency of the materials) and to the structure of the individual panel. In the particular case of photovoltaic panels, most of the light energy is not converted into electric energy but into energy of thermal agitation of the material, and the fluid-containing panel 13 is used to recover this energy. The thermal energy inevitably generated by the photovoltaic panel 11 is substantially transferred to the fluid-containing panel 13 by virtue of the steel plate 24.

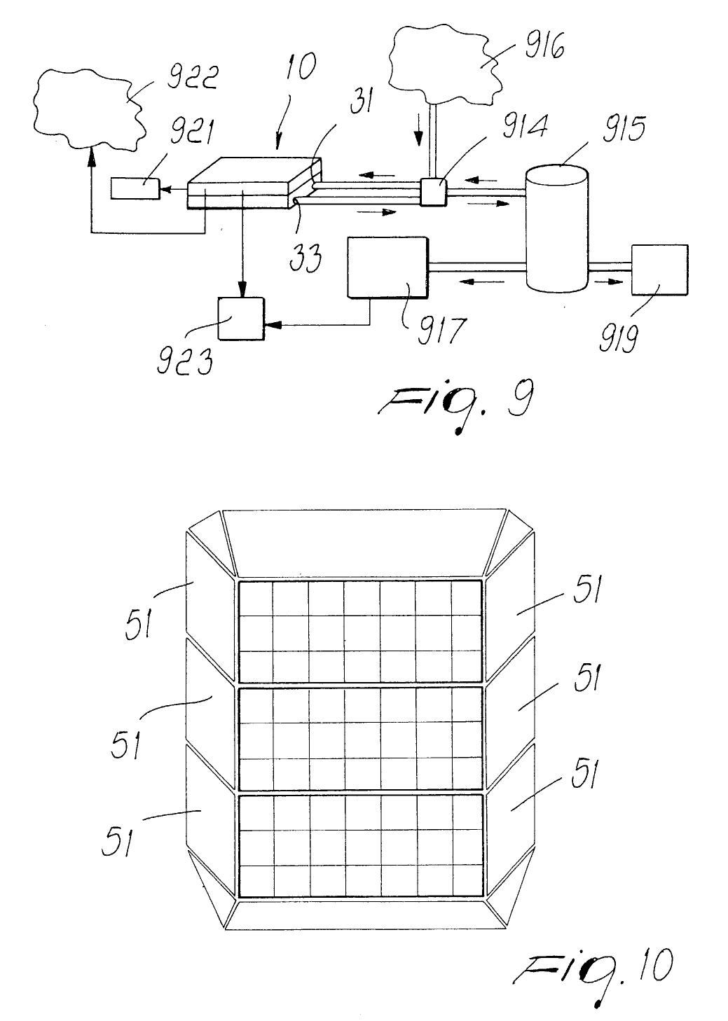

The fluid contained in the fluid-containing panel 13 is water in the particular embodiment and has the dual purpose of cooling the photovoltaic panel 11 and of conveying the thermal energy outward, so that it can be used for the most disparate purposes. Some examples are shown in FIG. 9: the water, injected into the input mouth 31, can be drawn by virtue of external fluid flow regulation means 914 from the hydraulic distribution system 916 or from a fluid accumulation tank 915, which in turn can be filled with the water that arrives from the output mouth 33 and passes through means for hydraulic connection between the tank and the panel. The fluid flow regulation means comprise at least one fluid recirculation pump for making the water circulate within the fluid-containing panel, and a second pump for drawing the fluid from the system 916; there may be also a third pump for drawing the fluid from and/or into the tank 915. The heat of the water accumulated in the tank can be used by a generic user device 919 or converted into electric energy by means of a thermoelectric converter 917. FIG. 9 shows the possible directions of the fluid inside the connecting tubes.

FIG. 9 also shows some of the possible uses of the electric power generated by the panel according to the invention, such as direct use by a generic user device 923, feeding to the low-voltage distribution system 922, or charging of batteries 921. The figure does not show, merely for the sake of simplicity in illustration, the conversion units required to convert the photogenerated direct current produced by the photovoltaic panel into alternating current, which in the case of a connection to a distribution system must be in phase with said system.

The cooling of the photovoltaic cells is very important for the efficiency of the panel: it has in fact been noted that a reduction of the operating temperature of the photovoltaic cells entails an increase in the current at the electrical terminals of the panel for an equal voltage. For example, if one considers a cell of polycrystalline silicon such as the ASE Main-Cell 100 mm×100 mm by Tessag, which has a thickness of 0.3 mm and is exposed to an irradiation of 100 mW/cm², for a voltage of 450 mV the current generated per unit surface of the cell is equal to approximately 15 mA/cm² at 75° C., whereas at 50° C. the photogenerated current density is approximately 28 mA/cm².

By virtue of the cooling system it is possible to increase the concentration of light on the photovoltaic panel 11 without running the risk of degrading the operation of the panel or even burning the photovoltaic cells: the concentration entails a considerable improvement both in terms of photoelectric conversion efficiency and in terms of electric power production.

To increase the concentration of light on the photovoltaic panel one uses, as mentioned, light-reflecting or -concentrating means 51, which in a particular embodiment of the invention are constituted by plane mirrors mounted along the perimeter of the panel with a preset orientation with respect to the panel. The dimensions and the orientation of the mirrors are chosen so as to have a compromise between an intended concentration and a structural geometry that does not affect the normal operation of the panel.

As regards the geometry, it is evident that the larger the surface of the mirror, the greater the amount of light reflected toward the photovoltaic panel: however, an excessively large surface dimension of an individual mirror would entail not only an undesirable space occupation and an excessive loading of the overall structure, but also a dangerous exposure to wind-type phenomena, which might threaten the integrity of the structure due to a “sail” effect. Moreover, if an array of solar panels of the invented type is produced, in order to generate a power level that is proportional to the number of panels used, the excessive extension of the mirrors would entail an undesirable shadowing effect among adjacent panels if the space available for placing said panels is limited.

As regards concentration, a concentration ratio C is defined as the ratio between the sum of the axial length of the photovoltaic panel L′ plus twice the maximum distance of acceptance 1 of the solar rays 27 from the edge of the panel, and said distance 1, i.e.,

$$C = \frac{{L}^{′} + 2 \; 1}{1} .$$

With reference to FIG. 6, the maximum acceptance distance 1 is the distance at which a ray of light 27, which is normal to the photosensitive surface 28 that is substantially directed toward the sun and has, in projection, a distance 1 from the edge 61 thereof, is reflected by a mirror in the point 63 toward the opposite edge of the panel 62. In this manner, all the rays that are parallel to said ray and have a distance from the edge 61 of the panel that is less than 1 are in any case incident to the photosensitive surface of the panel that is substantially directed toward the sun.

Using beta (β) to designate the inclination, with respect to the plane of the mirror 51, of the generic normal ray 27 that has a distance 1 set by the chosen concentration ratio, all the rays that are incident in the point 63 of the mirror 51 at an angle smaller than β are reflected in any case onto the photovoltaic surface. In a particular embodiment, an optimum value of the concentration ratio C has been found to be 3.4, which entails an inclination of the mirrors of approximately 67 sexagesimal degrees with respect to the panel.

The great concentration of luminous power makes it indispensable to use the fluid-containing panel, and in particular it is preferred to have means for regulating the flow of the fluid 914; as the person skilled in the art may notice from the particular embodiment shown in FIG. 6, the heating of the fluid due to the concentration of sunrays is not uniform along the entire hydraulic circuit 13b, since the fluid accumulates more and more heat as it approaches the output mouth 33. By adjusting the flow-rate of the fluid by virtue of the regulation means 914 (typically hydraulic pumps) it is thus possible to set at will the difference in temperature between the input mouth 31 and the output mouth 33, minimizing it so as to avoid degrading significantly the efficiency of the photovoltaic cells that lie above the output portion of the hydraulic circuit 13b.

According to a particular embodiment of the invention, the water that constitutes the cooling fluid is heated by a maximum of 5° C. between the input and output. In order to obtain a fluid that as a whole is hotter but has the same temperature differential between the input and the output, the regulation means 914 can be of a type able to recirculate the water inside the panel several times, bringing it to temperatures between 40 and 75° C.

The most important advantages relate not only to the thermal part of the panel but also to the electrical part. Considering an average irradiation of 1000 W/m², for a combined panel without concentrators 51 and constituted by a plurality of cells it is known that the photoelectric conversion efficiency of the panel as a whole degrades slightly with respect to the efficiency of the individual cell owing to the fact that an exposed light insensitive space necessarily exists between one cell and the adjacent cells: for a panel having a surface of 1.76 m², constituted by an array of 12×8 square cells of polycrystalline material with 13% efficiency and with individual dimensions of 125 mm×125 mm, an electrical efficiency of 11.36% was measured.

In this particular case, the thermal power produced with an average irradiation of 1000 W/m² was 1232 W (1060 kcal), and the generated electric power was 200 W.

A considerable increase in both thermal power and in electric power is obtained by means of the concentrators 51: in particular, the thermal power is generally tripled with respect to the case of a simple combined panel, while the electric power is approximately doubled. In the particular example described, the mirror concentration, according to the optimum inclination thereof, produces a thermal power of 3696 W (3180 kcal) and an electric power of over 400 W. Producing the same amount of thermal power as the panel according to the invention therefore would require three simple combined panels and the surface coverage would of course be increased significantly.

The reflective means 51 allow not only to have much more energy per unit surface of the photovoltaic panel but also to recover most of the light rays that would otherwise not intersect said surface and would therefore be lost.

It is possible to obtain concentrations on the order of 2.5 kW/m² from a single module whose overall surface dimensions are smaller than, for example, two combined panels, each having the same dimensions as the module without concentrator mirrors 51, arranged side by side to produce the same electric power; in other words, using the notation introduced earlier and with reference to FIG. 6, if one considers a square module with 21+L′<2L′, one produces at least the same electric power as two square mirror-less modules each having sides whose dimension is L′.

Such an increase in obtainable power levels allows a considerable reduction in energy production costs, a saving in terms of surface covered by the panel, and important applications, such as for example the utilization of the panel in regions that are scarcely illuminated by the sun, such as those located at high latitudes.

Among the possible applications, it is possible to provide arrays constituted by several panels according to the invention, or vectors such as the ones shown in FIG. 10, both embodiments being usable industrially.

The invention thus conceived is susceptible of numerous modifications and variations, all of which are within the scope of the inventive concept.

In practice, the materials used, as well as the contingent shapes and dimensions, may be any according to requirements. All the details may further be replaced with technically equivalent elements.

What is claimed is:

1. A solar panel for simultaneous generation of electric and thermal energy, comprising:
a photovoltaic panel for generating electric energy;
a supporting frame on which said photovoltaic panel is mounted;
a fluid-containing panel for cooling the photovoltaic panel and for generating thermal energy, which is mounted on the surface that lies opposite the surface of the photovoltaic panel that is substantially oriented toward the sun;
a heat exchanger, which is interposed between said photovoltaic panel and said fluid-containing panel to provide the thermal coupling between said photovoltaic panel and said fluid-containing panel; and
reflective means fitted on said supporting frame and orientated so as to direct solar radiation on said photovoltaic panel.

2. The solar panel according to claim 1, wherein said reflective means comprise plane mirrors or dielectric multilayers.

3. The solar panel according to claim 1, wherein said reflective means are rigidly coupled to the photovoltaic panel and are substantially arranged along the perimeter of the photovoltaic panel.

4. The solar panel according to claim 1, wherein said fluid-containing panel comprises a hydraulic circuit for conveying a fluid along the entire surface that lies opposite the surface of the photovoltaic panel that is substantially oriented toward the sun.

5. The solar panel according to claim 4, wherein said hydraulic circuit comprises at least one mouth for the inflow of the fluid into said fluid-containing panel and at least one mouth for outflow from said fluid-containing panel.

6. The solar panel according to claim 5, wherein said hydraulic circuit is connected to fluid flow regulation means in order to set the amount of heat exchanged by the fluid with the photovoltaic panel.

7. The solar panel according to claim 6, wherein said fluid flow regulation means comprise at least one recirculation pump that connects said input mouth to said output mouth.

8. The solar panel according to claim 6, wherein said fluid flow regulation means comprise means for drawing the fluid from a hydraulic distribution network.

9. The solar panel according to claim 6, further comprising at least one fluid accumulation tank, which is connected to said fluid-containing panel by virtue of hydraulic connection means and is mounted externally to the solar panel.

10. The solar panel according to claim 9, wherein said fluid flow regulation means comprise means for drawing the fluid from said fluid accumulation tank.

11. The solar panel according to claim 1, wherein said fluid-containing panel is constituted by a tank filled with said fluid and said photovoltaic panel and said heat exchanger are fixed to a raft that floats on said fluid.

12. The solar panel according to claim 1, wherein said fluid is composed of water.

13. The solar panel according to claim 1, wherein said photovoltaic panel comprises at least one photovoltaic cell whose upper photosensitive surface is oriented substantially toward the sun and rigidly coupled to at least one transparent protective layer, and whose lower surface is rigidly coupled to said heat exchanger.

14. The solar panel according to claim 13, further comprising an adhesive for fixing said upper photosensitive surface and said lower surface respectively to said transparent protective layer and said heat exchanger.

15. The solar panel according to claim 14, wherein said adhesive is constituted by ethyl vinyl acetate (EVA).

16. The solar panel according to claim 13, wherein said transparent protective layer has a surface extension that is substantially greater than said upper photosensitive surface.

17. The solar panel according to claim 13, wherein said transparent protective layer comprises a flat glass plate.

18. The solar panel according to claim 13, wherein said transparent protective layer is of the nonreflective type.

19. The solar panel according to claim 1, wherein said heat exchanger comprises a heat-conducting plate and said surface substantially oriented toward the sun comprises a transparent protective layer mounted thereon.

20. The solar panel according to claim 19, wherein said heat-conducting plate has substantially the same thermal expansion coefficient as the transparent protective layer.

21. The solar panel according to claim 19, wherein said heat-conducting plate is made of steel.

22. The solar panel according to claim 1, further comprising thermoelectric conversion means for converting into electric power the heat conveyed by the fluid.

23. The solar panel according to claim 22, wherein said thermoelectric conversion means comprise at least one fluid-based thermoelectric converter.

24. A method for producing electric power and thermal energy from a photovoltaic panel exposed to solar radiation, comprising the steps of:
concentrating the sunrays on said photovoltaic panel in order to increase the electric power generated by the photovoltaic panel; and
placing the photovoltaic panel in thermal contact with a fluid-containing panel in order to cool said photovoltaic panel and generate thermal energy.

25. The method according to claim 24, wherein the rays of the sun are concentrated by virtue of reflective means mounted substantially around the photovoltaic panel.

26. The method according to claim 25, wherein said reflective means comprise plane mirrors or dielectric multilayers.

27. The method according to claim 24, wherein thermal contact between the photovoltaic panel and the fluid-containing panel is provided by means of a heat exchanger.

28. The method according to claim 27, wherein said heat exchanger is a heat-conducting plate that is interposed between said photovoltaic panel and said fluid-containing panel.

29. The method according to claim 28, wherein said heat-conducting plate is made of steel.

30. The method according to claim 24, further comprising the step of generating thermal energy by extracting the fluid circulating in a hydraulic circuit contained in said fluid-containing panel heated by the photovoltaic panel.

31. The method according to claim 30, further comprising the step of regulating the flow-rate of the fluid that circulates in said fluid-containing panel by virtue of fluid flow regulation means.

32. The method according to claim 31, wherein said fluid flow regulation means comprise at least one recirculation pump, which connects at least one fluid input mouth of the fluid-containing panel to at least one fluid output mouth of the fluid-containing panel.

33. The method according to claim 24, wherein the fluid is made of water.
